(19) United States
(12) Patent Application Publication
(10) Pub. No.: US 2025/0181192 A1
(43) Pub. Date: Jun. 5, 2025

(54) DISPLAY DEVICE AND DRIVING METHOD FOR DISPLAY DEVICE

(71) Applicant: Shanghai Tianma Micro-Electronics Co., Ltd., Shanghai (CN)

(72) Inventors: Tomohiko OTOSE, Kawasaki (JP); Hisashi Hayashi, Kawasaki (JP); Kensuke Tamura, Kawasaki (JP); Akira Tanabe, Kawasaki (JP)

(73) Assignee: Shanghai Tianma Micro-Electronics Co., Ltd., Shanghai (CN)

(21) Appl. No.: 18/964,781

(22) Filed: Dec. 2, 2024

(30) Foreign Application Priority Data
Dec. 1, 2023 (JP) 2023-203838
Sep. 3, 2024 (JP) 2024-151543

(51) Int. Cl. G06F 3/041; G02F 1/1333; G09G 3/36; G11C 19/28

(52) U.S. Cl. CPC G06F 3/04184; G02F 1/13338; G06F 3/0412; G09G 3/3677; G09G 2310/0286; G09G 2310/08; G09G 2354/00; G11C 19/28

(57) ABSTRACT

A display device includes a display panel and, a scan line driver, and a touch detector. The display panel includes scan lines. The scan line driver includes a circuit group. The circuit group includes shift registers that include unit circuits that are multi-stage connected, and that sequentially output a scan signal to the scan lines of a display region of the display panel. The touch detector detects a touch in a stopping period of the circuit group. The shift registers sequentially output the scan signal as a result of a selection signal and a start signal being input into the unit circuits of a first stage. Each selection signal has a phase that mutually differs, and the start signal is commonly input into the unit circuits of the first stage.

### CROSS-REFERENCE TO RELATED APPLICATIONS

This application claims the benefit of Japanese Patent Application No. 2023-203838,

filed on Dec. 1, 2023, and Japanese Patent Application No. 2024-151543, filed on Sep. 3, 2024, of which the entirety of the disclosures is incorporated by reference herein.

### FIELD OF THE INVENTION

The present disclosure relates generally to a display device and a driving method for the display device.

### BACKGROUND OF THE INVENTION

In the related art, in-cell type display devices in which the functions of a touch sensor (touch panel) are incorporated into a display panel are known. In in-cell type display devices, pixel electrodes for driving the pixels of the display device are used for touch detection.

Accordingly, when performing touch detection, scanning of the scan lines of the display panel is temporarily stopped. Then, touch detection is performed in a stopping period in which the scanning of the scan lines is stopped. As a result, in the touch detection, it is possible to prevent the inclusion of noise caused by changes in the potential of the scan lines.

For example, US Patent Application Publication No. 2019/0114980 describes a display device that includes a display panel, a gate driving circuit, and a touch driving circuit. The display panel includes a display region including gate lines, data lines, and touch sensors. The gate driving circuit divides the display region into a plurality of horizontal blocks, and drives the gate lines of a horizontal block by units of the horizontal blocks, at every display period in one frame. The touch driving circuit detects touches via the touch sensors of the horizontal block by units of the horizontal blocks, at every touch detection period within the one frame.

In US Patent Application Publication No. 2019/0114980, the gate driving circuit includes a plurality of driving stage groups and a plurality of holding stage groups. The driving stage groups supply a scan pulse to the gate lines included in the corresponding horizontal block, at each display period. The holding stage groups supply, in accordance with an output signal supplied from a front driving stage group, a carry signal to the rear driving stage group between the driving stage groups. As a result, a display device is realized that includes a gate driving circuit that stably holds the output signal during the touch detection period or, rather, while the scanning of the gate lines is stopped.

In the gate driving circuit of US Patent Application Publication No. 2019/0114980, many signals are needed to drive the driving stage groups and the holding stage groups. For example, when the display region is divided into eight horizontal blocks, 20 signals (four gate start signals, eight gate shift clocks, four scan holding clocks, and four stage reset clocks) are needed (see paragraph 0067 of the description of US Patent Application Publication No. 2019/0114980). Accordingly, the number of signal wires of the gate driving circuit increases and, when forming the gate driving circuit in a frame portion of the display panel, the size of the outer shape of the display panel increases. Moreover, when incorporating the gate driving circuit into a driver integrated circuit (IC), the size of the driver IC increases.

Furthermore, in the driving stage groups of the gate driving circuit of US Patent Application Publication No. 2019/0114980, high voltage is constantly applied to an input terminal of a transistor that includes a gate terminal into which the start signal is input. Accordingly, a threshold value voltage shift may occur in the transistor that includes the gate terminal into which the start signal is input.

### SUMMARY OF THE INVENTION

A display device of a first aspect of the present disclosure includes:
a display panel that includes a plurality of scan lines, and a display portion that is divided into a plurality of display regions;
a scan line driver that sequentially outputs a scan signal to each of the scan lines; and
a touch detector that detects a touch on the display panel, wherein
the scan line driver includes at least one circuit group,
the circuit group includes a plurality of shift registers that include a plurality of unit circuits that are multi-stage connected, and that output the scan signal to each of the scan lines, and the plurality of shift registers sequentially output the scan signal to each of the scan lines within each of the display regions,
the touch detector detects the touch on the display panel in a stopping period in which the at least one circuit group stops outputting of the scan signal, and
in the one circuit group
   each of the shift registers sequentially outputs the scan signal as a result of a selection signal, for selecting the shift register to output the scan signal, and a start signal, for starting the outputting of the scan signal, being input into the unit circuit of each first stage,
   each of the selection signal input into each of the unit circuits of the first stage has a phase that mutually differs according to a scan period in which the circuit group outputs the scan signal and the stopping period, and
   the start signal is commonly input into each of the unit circuits of the first stage.

A driving method for a display device of a second aspect of the present disclosure, the display device including
a display panel including a plurality of scan lines and a display portion divided into a plurality of display regions, a display operation of displaying a display element and a touch detection being performed in an alternating manner, the driving method including:
displaying the display element or a portion of the display element in one of the display regions by sequentially outputting, from one of a plurality of shift registers that include a plurality of unit circuits and that sequentially output a scan signal to each of the scan lines within each of the plurality of display regions, the scan signal to each of the scan lines, the plurality of unit circuits being multi-stage connected and outputting the scan signal to the scan line; and
detecting a touch on the display panel in a stopping period in which the plurality of shift registers stops outputting of the scan signal, wherein
in the displaying of the display element or a portion of the display element,
   the scan signal is sequentially output from the one shift register of the plurality of shift registers as a result of a selection signal, for selecting the shift register to output the scan signal, and a start signal, for starting the outputting of the scan signal, being input into the unit circuit of a first stage of each of the shift registers,
   each of the selection signal input into each of the unit circuits of the first stage has a phase that mutually differs according to a scan period in which the plurality of the shift registers outputs the scan signal and the stopping period, and
   the start signal is commonly input into each of the unit circuits of the first stage.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a schematic drawing illustrating an overview of a display device according to Embodiment 1;

FIG. 2 is a schematic drawing illustrating a display region, scan lines, and data lines of a display panel according to Embodiment 1;

FIG. 3 is a schematic drawing illustrating a detection region, sensor electrodes, and sensor wires according to Embodiment 1;

FIG. 4 is a schematic drawing for explaining a display period and a detection period according to Embodiment 1;

FIG. 5 is a schematic drawing illustrating a scan line driver according to Embodiment 1;

FIG. 6 is a drawing illustrating a start signal and selection signals according to Embodiment 1;

FIG. 7 is a block diagram for explaining the configuration of a shift register according to Embodiment 1;

FIG. 8 is a drawing illustrating the circuit configuration of a unit circuit according to Embodiment 1;

FIG. 9 is a timing chart of the shift register according to Embodiment 1;

FIG. 10 is a flowchart illustrating driving processing according to Embodiment 1;

FIG. 11 is a schematic drawing illustrating a scan line driver according to Embodiment 2;

FIG. 12 is a drawing illustrating a start signal and selection signals according to Embodiment 2;

FIG. 13 is a schematic drawing illustrating a display region, scan lines, and data lines of a display panel according to Embodiment 3;

FIG. 14 is a schematic drawing illustrating a detection region, sensor electrodes, and sensor wires according to Embodiment 1;

FIG. 15 is a schematic drawing for explaining the display period and the detection period according to Embodiment 1;

FIG. 16 is a schematic drawing illustrating a scan line driver according to Embodiment 3;

FIG. 17 is a schematic drawing illustrating a unit circuit and a switching circuit of a first stage of a shift register of one circuit group according to Embodiment 3; and

FIG. 18 is a drawing illustrating a start signal, selection signals, and switching signals of the one circuit group according to Embodiment 3.

### DETAILED DESCRIPTION OF THE INVENTION

Hereinafter, a display device and a driving method for the display device according to various embodiments are described while referencing the drawings.

### Embodiment 1

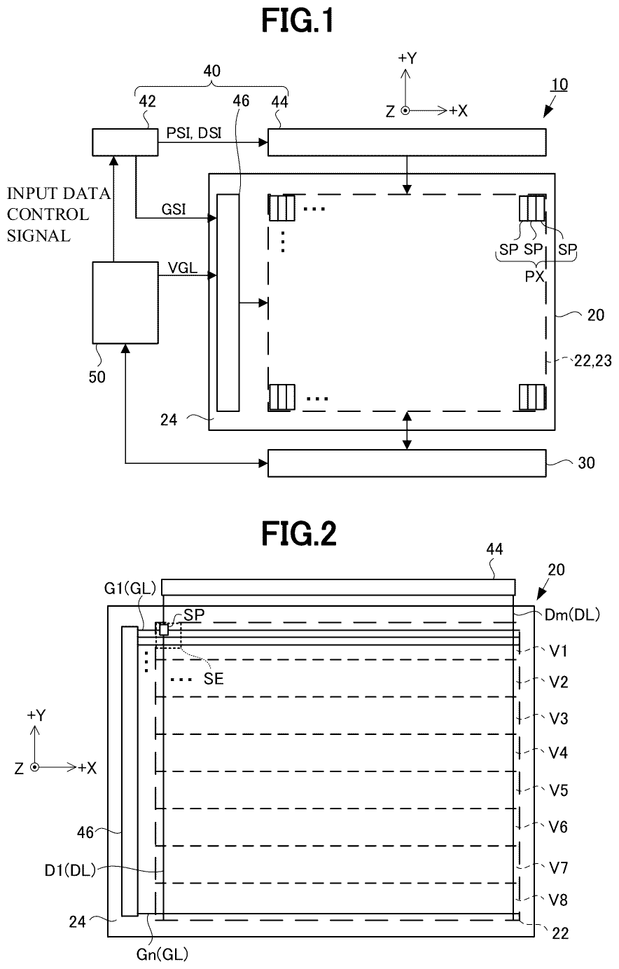

A display device 10 and a driving method for the display device 10 according to the present embodiment are described while referencing FIGS. 1 to 10. The display device 10 is mounted in a vehicle, an airplane, on a household appliance, a piece of furniture, or the like.

As illustrated in FIG. 1, the display device 10 includes a display panel 20, a touch detector 30, a display controller 40, and a controller 50. In one example, the display panel 20 is implemented as a color liquid crystal display panel, and displays a display element (text, images, and the like). The touch detector 30 detects a touch on the display panel 20. The display controller 40 causes the display panel 20 to display the display element. The display controller 40 includes a timing controller 42, a data line driver 44, and a scan line driver 46. The controller 50 controls the touch detector 30 and outputs the position of the detected touch. Additionally, input data (input image data) from external devices is input into the controller 50, and the controller 50 controls the display controller 40. Note that, in the present embodiment and the following embodiments, to facilitate comprehension, a description is given in which, in FIG. 1, the right direction (the right direction on paper) of the display panel 20 is referred to as the “+X direction”, the up direction (the up direction on paper) is referred to as the “+Y direction”, and the direction perpendicular to the +X direction and the +Y direction (the front direction on paper) is referred to as the “+Z direction.”

The display panel 20 of the display device 10 is an in-cell type color liquid crystal display panel that includes a function for displaying the display element and a function for detecting the touch. Here, the term “in-cell type color liquid crystal display panel” refers to a configuration including, on a main surface on the liquid crystal side of one of two substrates sandwiching the liquid crystal, electrodes used for touch detection. Additionally, the term “touch” means an object contacting the display panel 20, or an object coming close enough to the display panel 20 to form parasitic capacitance between the object and hereinafter described sensor electrodes SE of the display panel 20. The object is a finger of a user, a pen, or the like.

In one example, the display panel 20 is implemented as a known transmissive horizontal electric field type color liquid crystal display panel. The crystal display panel 20 is active matrix driven by thin film transistors (TFT), and displays the display element. As illustrated in FIG. 1, the display panel 20 includes a display portion 22, a detection region 23, and a frame portion 24.

In the display portion 22, a main pixel PX is disposed in a matrix, and displays the display element. Each main pixel PX is formed from three subpixels SP. The detection region 23 is a region in which the touch on the display panel 20 is detectable. The scan line driver 46, wiring, and the like are disposed in the frame portion 24. In the present embodiment, the display portion 22 and the detection region 23 match.

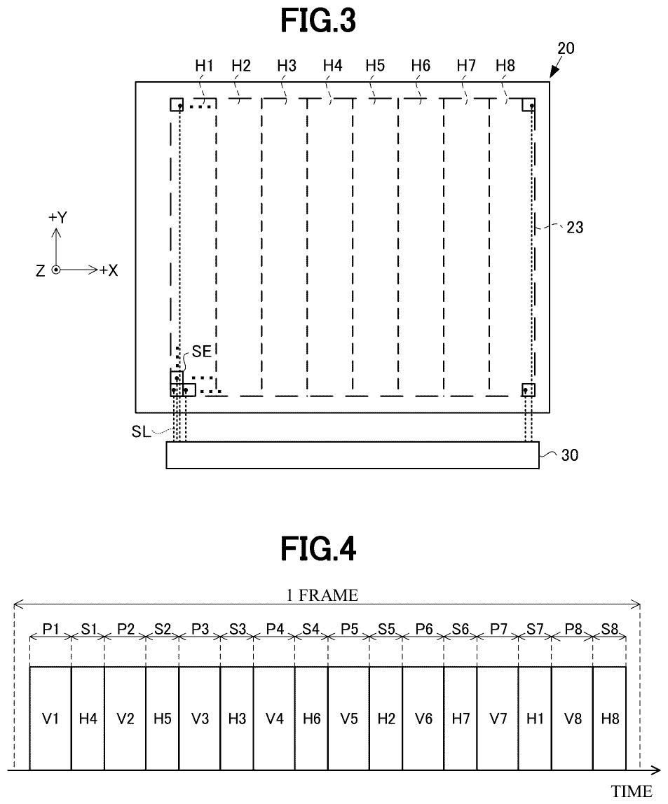

In the present embodiment, as illustrated in FIG. 2, the display portion 22 is divided into eight display regions V1 to V8 that extend in the X direction. Additionally, as illustrated in FIG. 3, the detection region 23 is divided into eight detection regions H1 to H8 that extend in the Y direction.

In the display device 10, a display operation for displaying the display element and touch detection are performed in an alternating manner in time divisions within one frame of displaying the display element on the display panel 20. Specifically, as illustrated in FIG. 4, the display operations in the display regions V1 to V8 are sequentially performed in display periods P1 to P8, respectively. The touch detection in one region among the detection regions H1 to H8 is performed in each of detection periods S1 to S8. For example, in FIG. 4, in the display period P1, the display operation in the display region V1 is performed, display scanning is stopped and, then, in the detection period S1, the touch detection in the detection region H4 is performed.

Then, after the touch detection in the detection period S1 is stopped, the display operation in the display region V2 is performed in the display period P2. That is, the touch detection is performed in a stopping period in which the display operation is stopped.

As illustrated in FIG. 2, the display panel 20 includes a plurality of scan lines G1 to Gn, and a plurality of data lines D1 to Dm. The scan lines G1 to Gn extend in the X direction and are arranged along the Y direction. The scan lines G1 to Gn are connected to the scan line driver 46. The data lines D1 to Dm extend in the Y direction and are arranged along the X direction. The data lines D1 to Dm are connected to the data line driver 44. In the following, the scan lines G1 to Gn are sometimes referred to collectively as “scan lines GL”, and the data lines DI to Dm are sometimes referred to collectively as “data lines DL.”

Subpixels SP are disposed at positions where the scan lines GL and the data line DL cross. In the present embodiment, three subpixels SP (for example, a subpixel SP that emits red light, a subpixel SP that emits green light, and a subpixel SP that emits blue light) form one main pixel PX.

Each of the subpixels SP includes a TFT, a pixel electrode, and a common electrode (all not illustrated in the drawings). Gate electrodes of the TFTs are connected to the scan lines GL, and source terminals of the TFTs are connected to the data lines DL. Additionally, drain terminals of the TFTs are connected to the pixel electrodes. In accordance with a scan signal supplied from each of the scan lines GL, each TFT supplies, to each pixel electrode, data voltage corresponding to a video signal supplied from each of the data lines DL. In one example, each pixel electrode has a comb-tooth shape, and is connected to the drain electrode of the TFT. The common electrodes are connected to a non-illustrated common wiring. In the present embodiment, the common electrode is divided into a plurality of sections, and the divided common electrode constitutes sensor electrodes SE. The liquid crystal of the display panel 20 controls, on the basis of a potential difference between a data voltage of the pixel electrode and a common voltage applied to the common electrode via the common wiring, an amount of light emitted from the subpixels SP.

As described above, the sensor electrodes SE are constituted from the divided common electrode. As illustrated in FIG. 3, the sensor electrodes SE are arranged in a matrix in the detection region 23. Each of the sensor electrodes SE is connected to the touch detector 30 via a sensor line SL. The sensor electrodes SE are provided with drive signals from the touch detector 30 via the sensor lines SL, and output, to the touch detector 30, response signals (output signals) to the drive signals. Note that the sensor lines SL are provided on a layer upward from (layer on the +Z side of) the scan lines GL and the data lines DL.

The touch detector 30 of the display device 10 is a circuit that detects whether there is a touch on the display panel 20 and the position of that touch. In each of the detection periods S1 to S8, the touch detector 30 detects whether there is a touch and the position of that touch in each of the detection regions H1 to H8. The touch detector 30 is connected to the sensor electrodes SE via the sensor lines SL. The touch detector 30 outputs various signals to the sensor electrodes SE in accordance with control signals (including synchronization signals) supplied from the controller 50. Additionally, the touch detector 30 receives the response signals output from the sensor electrodes SE. Furthermore, the touch detector 30 obtains the position of the touch from the response signals, and outputs a signal expressing the position of the touch to the controller 50. The touch detector 30 may, for example, be built into a touch display driver integration (TDDI).

Returning to FIG. 1, the display controller 40 of the display device 10 includes the timing controller 42, the data line driver 44, and the scan line driver 46.

The timing controller 42 converts input data (input image data), that expresses the display element and that is input from the controller 50, into a video signal PSI. The timing controller 42 outputs the converted video signal PSI to the data line driver 44. Additionally, the timing controller 42 generates, on the basis of the input data expressing the display element, the control signals including synchronization signals, and the like that are input from the controller 50, a control signal DSI for controlling the data line driver 44 and a control signal GSI for controlling the scan line driver 46. The timing controller 42 outputs the control signal DSI to the data line driver 44 and the control signal GSI to the scan line driver 46.

The data line driver 44 converts, on the basis of the control signal DSI, the video signal PSI supplied from the timing controller 42 to data voltage. The data line driver 44 outputs the converted data voltage to each of the data lines DL. The data line driver 44 and the timing controller 42 may, for example, be built into the TDDI.

The scan line driver 46 sequentially outputs, on the basis of the control signal GSI supplied from the timing controller 42, a scan signal to each of the scan lines GL. In one example, the scan line driver 46 is a circuit that is formed in the frame portion 24 of the display panel 20.

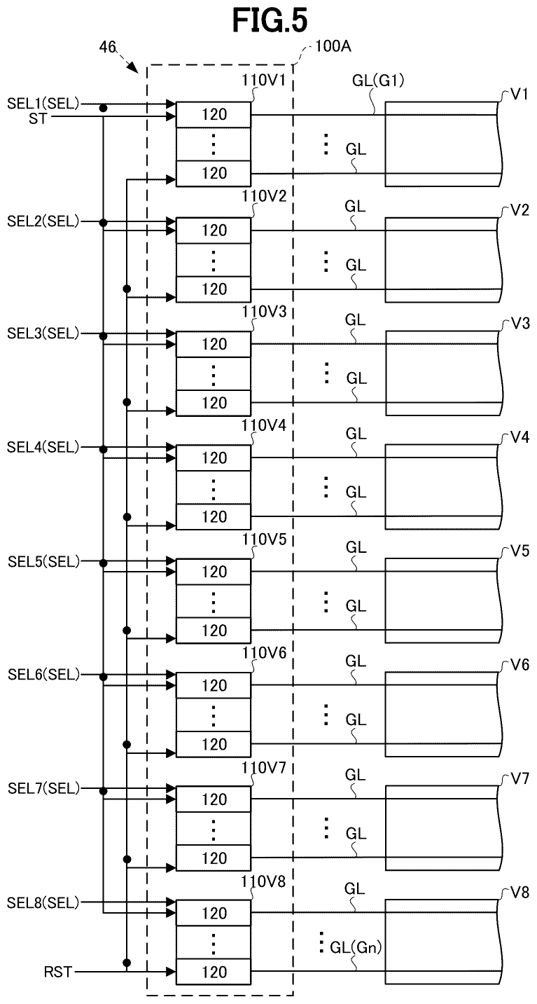

As illustrated in FIG. 5, the scan line driver 46 includes eight shift registers 110V1 to 110V8 that correspond to the display regions V1 to V8 of the display panel 20, respectively. Additionally, each of the shift registers 110V1 to 110V8 includes a plurality of unit circuits 120. The number of unit circuits 120 corresponds to the number of scan lines GL of each of the display regions V1 to V8. The unit circuits 120 are multi-stage connected. One of the unit circuits 120 outputs the scan signal to one of the scan lines GL.

The shift registers 110V1 to 110V8 may form at least one circuit group. In the present embodiment, an example is described of a case in which the shift registers 110V1 to 110V8 form one circuit group 100A. Specifically, in the present embodiment, the scan line driver 46 includes the one circuit group 100A, and the circuit group 100A includes the eight shift registers 110V1 to 110V8.

Note that, in the present embodiment, as described above, the shift registers 110V1 to 110V8 correspond to the display regions V1 to V8, respectively. Accordingly, each of the display regions V1 to V8 corresponds to a scan region of each of the shift registers 110V1 to 110V8. Additionally, a scan period in which each of the shift registers 110V1 to 110V8 outputs the scan signal corresponds to each of the display periods P1 to P8. In the following, the scan period of each of the shift registers 110V1 to 110V8 is referred to as scan period P1 to P8, and the scan periods (scan periods P1 to P8) may be collectively referred to as “scan periods P.”

The display operation and the touch detection are performed in an alternating manner (FIG. 4) and the touch detection is performed in the stopping period in which the display operation is stopped. As such, the touch detection is also expressed as being performed in the stopping period in which the outputting of the scan signal by the shift registers 110V1 to 110V8 is stopped, and the stopping periods correspond to the detection periods S1 to S8. In the following, the stopping period of each of the shift registers 110V1 to 110V8 is referred to as stopping period S1 to S8, and the stopping periods (stopping periods S1 to S8) may be collectively referred to as “stopping periods S.”

In the present embodiment, each of the shift registers 110V1 to 110V8 subsequently outputs the scan signal from each of the unit circuits 120 as a result of the start signal ST and the selection signals SEL being input into the unit circuit 120 of the first stage of each of the shift registers 110V1 to 110V8. In the following, the selection signals SEL input into each of the shift registers 110V1 to 110V8 are referred to as selection signals SEL1 to SEL8. Additionally, the shift registers (shift registers 110V1 to 110V8) may be referred to collectively as “shift registers 110.”

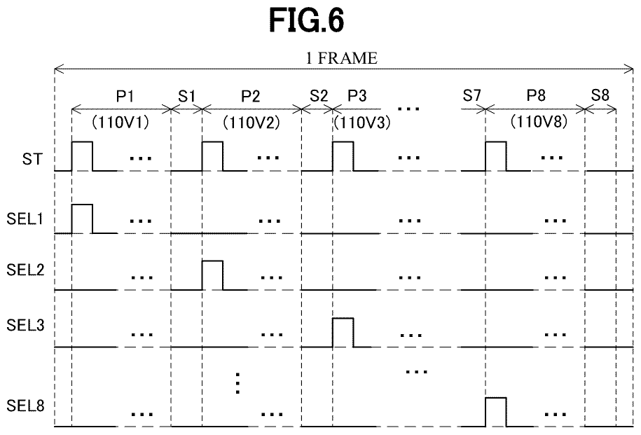

The start signal ST is a signal for starting the outputting of the scan signal. The start signal ST is commonly input into each of the unit circuits 120 of the first stage of the shift registers 110V1 to 110V8. The selection signals SEL1 to SEL8 are signals for selecting the shift registers 110 that output the scan signal. As illustrated in FIG. 6, the selection signals SEL1 to SEL8 have phases that mutually differ in accordance with the scan period P in which the shift registers 110V1 to 110V8 (that is, the circuit group 100A) outputs the scan signal, and the stopping periods S in which the shift registers 110V1 to 110V8 stop the outputting of the scan signal. The phases of the selection signals SEL1 to SEL8 mutually differ in accordance with the scan periods P and the stopping periods S and, as such, even when the start signal ST is commonly input into each of the unit circuits 120 of the first stage, the scan signal is sequentially output from the one shift register 110 into which the selection signal SEL is input.

In the present embodiment, the start signal ST for starting the outputting of the scan signal is commonly input into each of the unit circuits 120 of the first stage of the shift registers 110V1 to 110V8, and the selection signals SEL, that have different phases and that are for selecting the shift registers 110 that output the scan signal, are input into each of the unit circuits 120 of the first stage. As such, the number of signal wires can be reduced. In the following, a specific example of the configuration of the shift registers 110 is described.

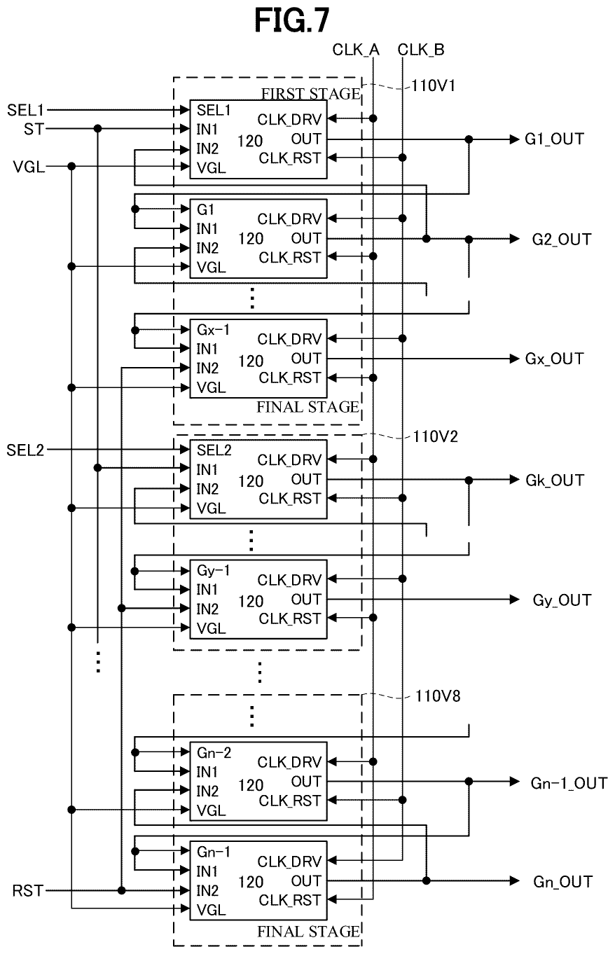

FIG. 7 is a block diagram for explaining the configuration of the shift registers 110. The start signal ST, one of the selection signals SEL1 to SEL8, a reset signal RST, two clock signals having inverted phases, namely, clock signal CLK_A and clock signal CLK_B, a frame reset signal FRM, and a low-level voltage VGL are input into the shift registers 110. Note that, to facilitate comprehension, the frame reset signal FRM is omitted from FIG. 7. The frame reset signal FRM is a signal for resetting the shift register 110 at the start of one frame.

The start signal ST, the selection signals SEL1 to SEL8, the reset signal RST, the clock signal CLK_A, the clock signal CLK_B, and the frame reset signal FRM correspond to the control signal GSI supplied from the timing controller 42. In one example, the low-level voltage VGL is supplied from the controller 50. In the following, the output signal corresponds to the scan signal.

In the scan period P1, when the start signal ST, commonly input into all of the unit circuits 120 of the first stage, and the selection signal SEL1, having a phase that differs from the other selection signals SEL2 to SEL 8, are input into the unit circuit 120 of the first stage of the first shift register 110V1, the unit circuit 120 of the first stage of the shift register 110V1 outputs an output signal (that is, the scan signal) G1_OUT from an output terminal OUT to the scan line G1 on the basis of the clock signals CLK_A and CLK_B. The output signal G1_OUT output from the unit circuit 120 of the first stage of the shift register 110V1 is input into the unit circuit 120 of second stage (next stage), and the unit circuit 120 of the second stage outputs an output signal G2_OUT to the next scan line G2 (GL) on the basis of the inputted output signal and the clock signals CLK_A and CLK_B. Meanwhile, the output signal G2_OUT output from the unit circuit 120 of the second stage (next stage) is also supplied to the unit circuit 120 of the first stage (previous stage).

As with the unit circuit 120 of the first stage and the unit circuit 120 of the second stage described above, the unit circuits 120 of the third stage and thereafter of the shift register 110V1 sequentially output output signals G3_OUT to Gx_OUT to the scan lines GL in the display region V1. When the unit circuit 120 of the final stage outputs the output signal Gx_OUT, the outputting of the output signal from the shift register 110V1 to the scan lines GL in the display region V1, in the scan period P1, stops. Note that the reset signal RST, that is commonly input into all of the unit circuits 120 of the final stage, is input into the unit circuit 120 of the final stage instead of the output signal of the next stage.

When the outputting of the output signal (scan signal) from the shift register 110V1 is stopped, in the detection period S1 (stopping period S1), the touch detection in one region among the detection regions H1 to H8 (detection region H4 in the present embodiment) is performed by the touch detector 30.

When the touch detection in the detection period S1 (stopping period S1) is ended, in the scan period P2, as in the scan period P1, output signals (scan signals) Gk_OUT to Gy_OUT are sequentially output from the second shift register 110V2 to the scan lines GL in the display region V2. In this case, the start signal ST, that is commonly input into all of the unit circuits 120 of the first stage, and the selection signal SEL2, that has a phase that differs from the other selection signals SEL1, and SEL3 to SEL 8, are input into the unit circuit 120 of the first stage of the shift register 110V2.

As with the first shift register 110V1 and the second shift register 110V2, for the third shift registers 110 and thereafter (shift registers 110V3 to 110V8) as well, outputting of the output signals and the touch detection are performed in an alternating manner.

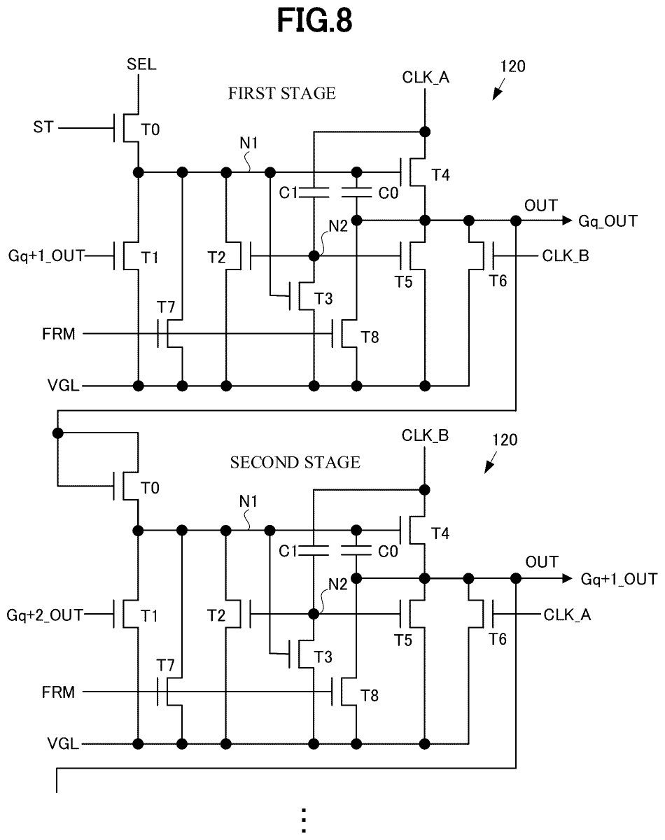

FIG. 8 is a drawing illustrating the circuit configuration of a unit circuit 120. The unit circuit 120 includes nine transistors T0 to T8, and two capacitors C0, C1.

In the unit circuit 120 of the first stage, the start signal ST is input into a gate terminal of the transistor T0, and the selection signal SEL is input into a first terminal of the transistor T0. A second terminal of the transistor T0 of the unit circuit 120 of the first stage is connected to a node N1. In the unit circuit 120 of the second stage and thereafter, the gate terminal and the first terminal of the transistor T0 are diode connected, and the output signal (scan signal) output from the unit circuit 120 of the previous stage is input into the diode connected gate terminal and first terminal. As with the unit circuit 120 of the first stage, the second terminal of the transistor T0 of the unit circuit 120 of the second stage and thereafter is connected to the node N1. The transistor T0 corresponds to a second transistor, and boosts the node N1.

Note that, in the present embodiment of the present disclosure, the first terminal of the transistor T0 refers to one of a source terminal and a drain terminal, and the second terminal of the transistor T0 refers to the other of the source terminal and the drain terminal. The same is true for the other transistors as well.

The output signal output from the unit circuit 120 of the next stage (second stage) is input into the gate terminal of the transistor T1. The first terminal of the transistor T1 is connected to the node N1, and the second terminal of the transistor T1 is connected to the signal wire that supplies the low-level voltage VGL. Note that, in the unit circuit 120 of the final stage, the reset signal RST is input into the gate terminal of the transistor T1 instead of the output signal output from the unit circuit 120 of the next stage.

The gate terminal of the transistor T2 is connected to a node N2. The first terminal of the transistor T2 is connected to the node N1. The second terminal of the transistor T2 is connected to the signal wire that supplies the low-level voltage VGL.

The gate terminal of the transistor T3 is connected to the node N1. The first terminal of the transistor T3 is connected to the node N2. The second terminal of the transistor T3 is connected to the signal wire that supplies the low-level voltage VGL.

One terminal of the capacitor C1 is connected to the node N2. The clock signal CLK_A or the clock signal CLK_B is input into the other terminal of the capacitor C0.

The gate terminal of the transistor T4 is connected to the node N1. The clock signal CLK_A or the clock signal CLK_B is input into the first terminal of the transistor T4. The second terminal of the transistor T4 is connected to an output terminal OUT. The transistor T4 corresponds to a first transistor.

One terminal of the capacitor C0 is connected to the gate terminal of to the transistor T4. The other terminal of the capacitor C0 is connected to the second terminal (output terminal OUT) of the transistor T4. That is, the capacitor C0 is connected between the gate terminal and the second terminal of the transistor T4.

The gate terminal of the transistor T5 is connected to the node N2. The first terminal of the transistor T5 is connected to the output terminal OUT. The second terminal of the transistor T5 is connected to the signal wire that supplies the low-level voltage VGL.

The clock signal CLK_A or the clock signal CLK_B is input into the gate terminal of the transistor T6. The first terminal of the transistor T6 is connected to the output terminal OUT. The second terminal of the transistor T6 is connected to the signal wire that supplies the low-level voltage VGL.

The frame reset signal FRM is input into the gate terminal of the transistor T7. The first terminal of the transistor T7 is connected to the node N1. The second terminal of the transistor T7 is connected to the signal wire that supplies the low-level voltage VGL.

The frame reset signal FRM is input into the gate terminal of the transistor T8. The first terminal of the transistor T8 is connected to the output terminal OUT. The second terminal of the transistor T8 is connected to the signal wire that supplies the low-level voltage VGL.

In the present embodiment, the selection signals SEL are input into the first terminal of the transistor T0 of the unit circuits 120 of the first stage and, as such, voltage is not constantly input into the first terminal of the transistor T0 of the unit circuits 120 of the first stage. Accordingly, bias voltage between the gate terminal and the first terminal in the transistor T0 of the unit circuits 120 of the first stage can be suppressed, and threshold value voltage shift of the transistor T0 of the unit circuits 120 of the first stage can be suppressed. Furthermore, in the unit circuits 120 of the second stage and thereafter, the gate terminal and the first terminal of the transistor T0 are diode connected and, as such, bias voltage can be suppressed and threshold value voltage shift can also be suppressed in the transistor T0 of the unit circuits 120 of the second stage and thereafter.

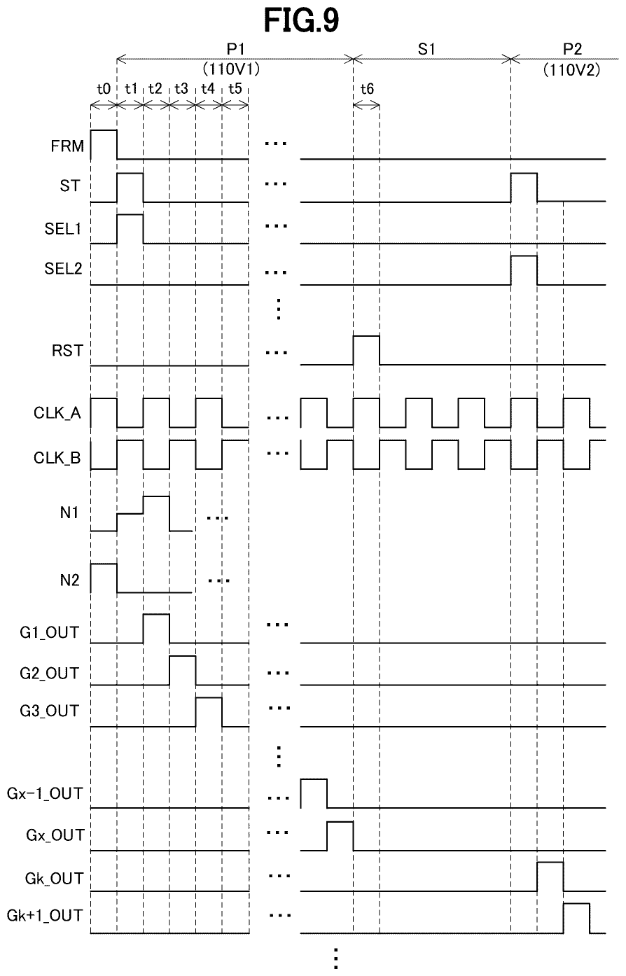

Next, the operations of the shift registers 110 are described while referencing FIG. 9. FIG. 9 is a timing chart of the shift registers 110. To facilitate comprehension, in FIG. 9, the potentials of the node N1 and the node N2 are illustrated only for the unit circuit 120 of the first stage of the scan period P1 (the shift register 110V1) and, thereby, the timing chart is simplified.

In a first period to within one frame, in all of the unit circuits 120, the frame reset signal is at a high level and, as a result, the transistors T7 and T8 assume an ON state. Due to the transistor T7 assuming the ON state, the node N1 is connected to the signal wire that supplies the low-level voltage VGL, and becomes low potential. Additionally, due to the transistor T8 assuming the ON state, the output terminal OUT also is connected to the signal wire that supplies the low-level voltage VGL, and becomes low level (low output).

In the next period t1, in the unit circuit 120 of the first stage of the shift register 110V1, the start signal ST commonly inputted into all of the unit circuits 120 of the first stage becomes high level. As a result, the transistor T0 assumes the ON state. Due to the transistor T0 assuming the ON state, the high potential of the selection signal SEL1, among the selection signals SEL1 to SEL8 that have mutually different phases, is applied to the node N1, and the node N1 becomes high potential. Due to the node N1 becoming high potential, the transistors T3 and T4 assume the ON state.

Due to the transistor T3 assuming the ON state, the potential of the node N2 is connected to the signal wire that supplies the low-level voltage VGL and decreases to low potential. The transistor T4 is in the ON state, but since the clock signal CLK_A is at the low level, the transistor T6 is in the ON state due to the clock signal CLK_B, and the output terminal OUT is connected to the signal wire that supplies the low-level voltage VGL, the output terminal OUT maintains the low level. Meanwhile, the node potential of the node N1 is held at the capacitor C0 connected between the gate terminal and the second terminal of the transistor T4. This node potential is obtained by subtracting the threshold value voltage of the transistor T0 from the high level potential of the selection signal SEL1.

In the next period t2, in the unit circuit 120 of the first stage of the shift register 110V1, the start signal ST and the selection signal SEL1 are at the low level and, as such, the node N1 assumes a floating state. The capacitor C0 has the potential held in the period t1 and, as such, the transistor T4 maintains the ON state. At this time, the clock signal CLK_A becomes high level and, due to the parasitic capacitance of transistor T4 and the capacitive coupling of the capacitor C0, the gate potential (the potential of the node N1) of the transistor T4 rises rapidly (bootstrap effect). Due to the rapid rise of the gate potential of the transistor T4, the high level of the clock signal CLK_A is output from the output terminal OUT as the output signal (scan signal) G1_OUT. The transistor T3 assumes the ON state due to the potential of the node N1 and, as such, the node N2 is connected to the signal wire that supplies the low-level voltage VGL, and becomes low potential.

In the next period t3, in the unit circuit 120 of the first stage of the shift register 110V1, the clock signal CLK_A changes to low level and the clock signal CLK_B changes to high level. As a result, the transistor T6 assumes the ON state, and the potential (voltage) held in the capacitor C0 is discharged. The output signal G2_OUT of the unit circuit 120 of the second stage (latter stage) is applied to the transistor T1 and, as a result, the node N1 is connected to the signal wire that supplies the low-level voltage VGL, and becomes low potential. The node N2 is in the floating state, and maintains the low potential in the period t2.

In the next period t4, in the unit circuit 120 of the first stage of the shift register 110V1, the clock signal CLK_A changes to high level. Additionally, the node N2 becomes high potential due to the high level potential of the clock signal CLK_A being held in the capacitor C1. As a result, the transistor T2 assumes the ON state, and the node N1 is connected to the signal wire that supplies the low-level voltage VGL. Additionally, the transistor T5 assumes the ON state, and the output terminal OUT is connected to the signal wire that supplies the low-level voltage VGL.

In the next period t5, in the unit circuit 120 of the first stage of the shift register 110V1, the clock signal CLK_A changes to low level. As a result, the node N2 discharges the potential of the capacitor C1 and becomes low potential.

Here, returning to the period t3, in the unit circuit 120 of the second stage of the shift register 110V1, the output signal of the unit circuit 120 of the first stage (previous stage) is input into the diode connected gate terminal and first terminal of the transistor T0. As a result, as with the unit circuit 120 of the first stage, the output signal G2_OUT is output from the output terminal OUT, from the unit circuit 120 of the second stage.

As with the unit circuit 120 of the second stage, the unit circuits 120 of the third stage and thereafter of the shift register 110V1 also sequentially output the output signals from the output terminal OUT.

The unit circuit 120 of the final stage of the shift register 110V1 outputs the output signal Gx_OUT and, as a result, the scan period P1 ends and the stopping period S1 (detection period S1), in which the outputting of the scan signals (output signals) from the shift registers 110 is stopped, starts. In a period t6 that is the first period of the stopping period S1, the reset signal RST that is commonly inputted into all of the unit circuits 120 of the final stage is inputted into the transistor T1 of the unit circuit 120 of the final stage of the shift register 110V1. As a result, the transistor T1 assumes the ON state, and the node N1 of the unit circuit 120 of the final stage becomes low potential. In the stopping period S1, the touch detection is performed by the touch detector 30.

When the touch detection in the stopping period S1 ends, the scan period P2 starts and, in the unit circuit 120 of the first stage of the shift register 110V2, the start signal ST becomes high level, and the high potential of the selection signal SEL2, among the selection signals SEL1 to SEL8 having mutually different phases, is applied to the node N1. Moreover, as with the shift register 110V1, the shift register 110V2 sequentially outputs output signals Gk_OUT to Gy_OUT. Thereafter, as with the shift register 110V2, the shift registers 110V3 to 110V8 sequentially output the output signals.

The controller 50 of the display device 10 controls the entire display device 10 on the basis of commands from an external device. The controller 50 outputs input data (input image data) expressing the display element to the display controller 40 (the timing controller 42). Additionally, the controller 50 outputs control signals including synchronization signals to the touch detector 30 and the display controller 40 (the timing controller 42). Furthermore, the controller 50 supplies the low-level voltage VGL to the scan line driver 46 (the shift registers 110) of the display controller 40.

In one example, the controller 50 includes a central processing unit (CPU), a read only memory (ROM), a random access memory (RAM), and a power supply circuit. In one example, the CPU executes programs stored in the ROM to realize the functions of the controller 50.

As described above, in the present embodiment, the start signal ST, that starts the outputting of the scan signals (the output signals), is commonly input into each of the unit circuits 120 of the first stage of the shift registers 110V1 to 110V8. Additionally, the selection signals SEL1 to SEL8, that have different phases and that are for selecting the shift registers 110 that output the scan signals, are input into each of the unit circuits 120 of the first stage. As a result, the signal wires that supply the start signal ST to each of the unit circuits 120 of the first stage of the shift registers 110V1 to 110V8 can be made common, and the number of signal wires can be reduced. For example, when, as in the present embodiment, the display portion 22 is divided into eight display regions V1 to V8, 13 signals (the start signal ST, the selection signals SEL1 to SEL8, the reset signal RST, the clock signals CLK_A and CLK_B, and the frame reset signal FRM) are supplied to the shift registers 110 as the control signal GSI. The number of signal wires for supplying these signals is merely 13.

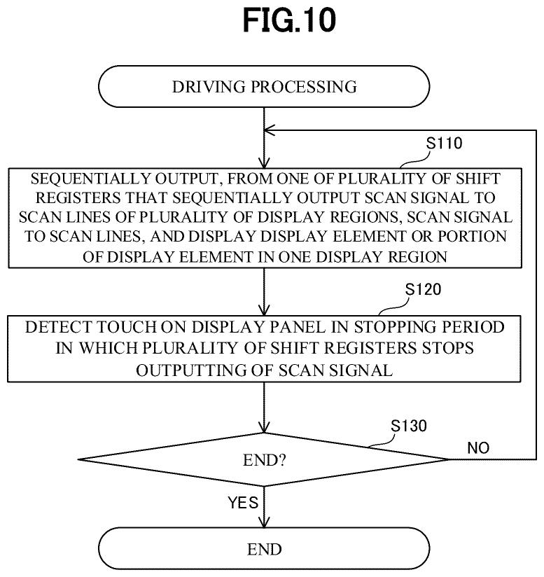

Next, driving processing for the display device 10 (that is, a driving method for the display device 10) is described while referencing FIG. 10. As illustrated in FIG. 10, the driving processing includes display processing (step S110) and touch detection processing (step S120). In the driving processing, the display processing (step S110) and the touch detection processing (step S120) are performed in an alternating manner.

In the display processing (step S110), scan signals (output signals) are sequentially output, from one of the eight shift registers 110V1 to 110V8 that sequentially output the scan signals, to the scan lines GL within each of the eight display regions V1 to V8 of the display panel 20, and the display element or a portion of the display element are displayed in the corresponding display regions V1 to V8. When the outputting of the scan signals from one of the shift registers 110 ends, the outputting of the scan signals from the eight shift registers 110V1 to 110V8 stops. Each of the eight shift registers 110V1 to 110V8 includes a plurality of unit circuits 120 that are multi-stage connected. One unit circuit 120 outputs the scan signals to one of the scan lines GL.

Firstly, the timing controller 42 of the display controller 40 sequentially outputs, on the basis of the control signals from the controller 50, scan signals to the scan lines GL within the corresponding display regions V1 to V8 from one of the shift registers 110V1 to 110V8 of the scan line driver 46 of the display controller 40. In this case, the timing controller 42 inputs the selection signals SEL and the start signal ST into the unit circuit 120 of the first stage of each of the shift registers 110V1 to 110V8. The start signal ST is a signal for starting the outputting of the scan signals, and is commonly input into each of the unit circuits 120 of the first stage. The selection signals SEL are signals for selecting the shift register 110 that outputs the scan signals. The phases of the selection signals SEL differ according to the scan period P in which the shift register 110 outputs the scan signals, and the stopping period S in which the shift register 110 stops the outputting of the scan signals. As a result, even when the start signal ST is commonly input into each of the unit circuits 120 of the first stage, the scan signals are sequentially output from one shift register 110 into which the selection signal SEL is input.

Specifically, the timing controller 42 inputs the selection signal SEL1 and the start signal ST into the unit circuit 120 of the first stage of the shift register 110V1. The start signal ST is commonly input into all of the unit circuits 120 of the first stage. The selection signal SEL1 has a phase that differs from the phases of the other selection signals SEL2 to SEL8, according to the scan period P and the stopping period S. Due to this, the scan signals are sequentially output, from only the shift register 110V1, to the scan lines GL within the corresponding display region V1.

Meanwhile, the timing controller 42 outputs, from the data line driver 44 and on the basis of the control signals from the controller 50, data voltage corresponding to the scan lines GL, to which the scan signals are output from the shift registers 110, to each of the data lines DL. Specifically, the timing controller 42 outputs, from the data line driver 44, data voltage corresponding to the display element or a portion of the display element to be displayed in the display region V1.

Thus, the display element or a portion of the display element is displayed in one of the display regions (the display region V1).

In the touch detection processing (step S120), a touch on the display panel 20 is detected in the stopping periods S1 to S8 in which the shift registers 110V1 to 110V8 stop the outputting of the scan signals. The touch detector 30 applies, on the basis of the control signals of the controller 50, a drive signal to the sensor electrode within one detection region (for example, detection region H4) among the detection regions H1 to H8, and receives a response signal. As a result, a touch on the display panel 20 is detected. When the touch detection processing (step S120) ends, the driving processing returns to the display processing (step S110).

In the driving processing of the display device 10, the display processing (step S110) and the touch detection processing (step S120) are repeated and, in the display processing (step S110), the display element or a portion of the display element is subsequently displayed in the display regions V1 to V8. When an end command is input from the controller 50 (step S130; YES), the driving processing of the display device 10 is ended.

As described above, the start signal ST for starting the outputting of the scan signals is commonly input into each of the unit circuits 120 of the first stage of the shift registers 110, and the selection signals SEL1 to SEL8, that have mutually different phases and that are for selecting the shift registers 110 that output the scan signals, are input into each of the unit circuits 120 of the first stage. As such, the signal wires that supply the start signal ST can be made common. Accordingly, it is possible to reduce the number of signal wires that supply signals to the scan line driver 46 of the display device 10. That is, it is possible to reduce the number of signal wires of the display device 10.

The reset signal RST is commonly input into the unit circuit 120 of the final stage of the shift registers 110 and, as such, the number of signal wires that supply the reset signal can be reduced and the signal wires of the display device 10 can be further reduced.

Additionally, the selection signals SEL are input into the first terminal of the transistor T0 of the unit circuit 120 of the first stage and, as such, threshold value voltage shift of the transistor T0 of the unit circuit 120 of the first stage can be suppressed. Furthermore, in the unit circuit 120 of the second stage and thereafter, the gate terminal and the first terminal of the transistor T0 are diode connected and, as such, threshold value voltage shift can be suppressed also in the transistor T0 of the unit circuit 120 of the second stage and thereafter.

### Embodiment 2

In Embodiment 1, the eight shift registers 110V1 to 110V8 form one circuit group 100A. However, a configuration is possible in which the eight shift registers 110V1 to 110V8 form two circuit groups 100A, 100B. In the following, the circuit groups (circuit group 100A, 100B) may be referred to collectively as “circuit groups 100.”

As with the display device 10 of Embodiment 1, a display device 10 of the present embodiment includes a display panel 20, a touch detector 30, a display controller 40, and a controller 50. With the exception of the scan line driver 46 of the display controller 40, the configuration of the display device 10 of the present embodiment is the same as that of the display device 10 of Embodiment 1 and, as such, the scan line driver 46 of the present embodiment is described.

As with the scan line driver 46 of Embodiment 1, the scan line driver 46 of the present embodiment includes eight shift registers 110V1 to 110V8 that correspond to the display regions V1 to V8 of the display panel 20, respectively. The configurations of the shift registers 110 and the unit circuit 120 of the present embodiment are the same as in Embodiment 1. Additionally, in the present embodiment as well, each of the shift registers 110V1 to 110V8 subsequently outputs scan signals from each of the unit circuits 120 as a result of the start signal ST and the selection signals SEL being input into the unit circuits 120 of the first stage of each of the shift registers 110V1 to 110V8.

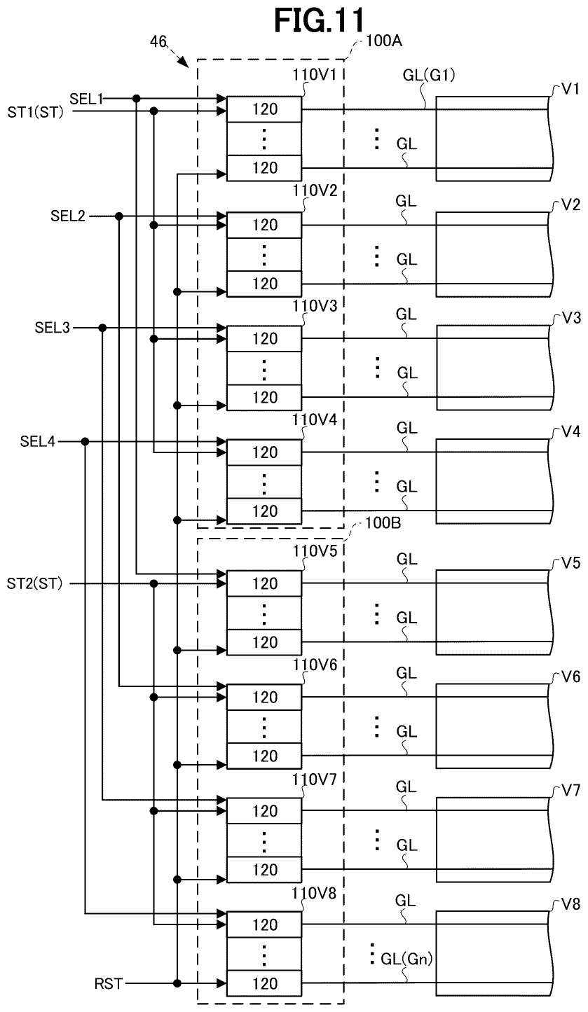

In the present embodiment, as illustrated in FIG. 11, the shift registers 110V1 to 110V8 form two circuit groups 100A, 100B. Specifically, the shift registers 110V1 to 110V4 form the circuit group 100A, and the shift registers 110V5 to 110V8 form the circuit group 100B.

As with the circuit group 100A of Embodiment 1, the circuit group 100A and the circuit group 100B each sequentially output scan signals. Additionally, the circuit group 100A and the circuit group 100B sequentially output the scan signals according to the stopping period S.

In the present embodiment, as the start signal ST, a start signal ST1 is input into the circuit group 100A, and a start signal ST2 is input into the circuit group 100B. As the selection signals SEL, the selection signals SEL1 to SEL4 are input into the circuit group 100A and the circuit group 100B. Note that the reset signal RST, the clock signal CLK_A, the clock signal CLK_B, the frame reset signal FRM, and the low-level voltage VGL are the same as in Embodiment 1.

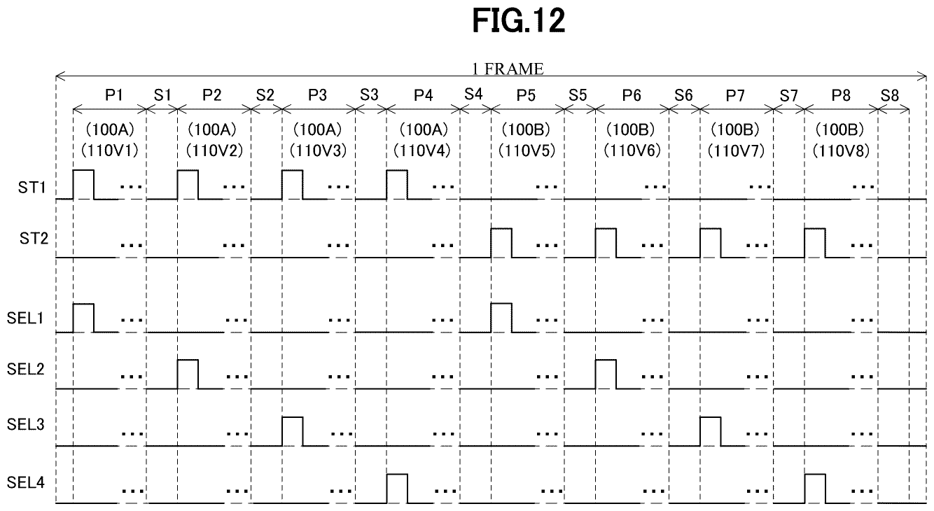

As with the circuit group 100A of Embodiment 1, in the circuit group 100A of the present embodiment 2, the start signal ST1 is commonly input into each of the unit circuits 120 of the first stage of the shift registers 110V1 to 110V4, as illustrated in FIGS. 11 and 12.

Additionally, in the circuit group 100B, the start signal ST2 is commonly input into each of the unit circuits 120 of the first stage of the shift registers 110V5 to 110V8. Accordingly, in the circuit group 100A or the circuit group 100B, the signal wires that supply the start signal ST1 or the start signal ST2 can be made common.

After the outputting of the scan signals of the circuit group 100A (the outputting of the unit circuit 120 of the final stage of the shift register 110V4) ends, an interval equivalent to the stopping period S (equivalent to the stopping period S4) is provided and, then, the start signal ST2 is commonly input into the unit circuits of the first stage of the shift registers 110 of the circuit group 100B. As a result, the circuit group 100A and the circuit group 100B sequentially output the scan signals.

As illustrated in FIGS. 11 and 12, the selection signals SEL1 to SEL4 have mutually different phases according to the scan period P and the stopping period S, and are each commonly input into each of unit circuit of the first stage of the shift registers 110 of the two circuit groups 100A, 100B. For example, the selection signal SEL1 is commonly input into the unit circuit 120 of the first stage of the shift register 110V1 of the circuit group 100A and the unit circuit 120 of the first stage of the shift register 110V5 of the circuit group 100B. As a result, the signal wires that supply the selection signals SEL1 to SEL4 to the unit circuits 120 of the first stage of the shift registers 110 of the circuit group 100A and the signal wires that supply the selection signals SEL1 to SEL4 to the unit circuits 120 of the first stage of the shift registers 110 of the circuit group 100B can be made common. In the present embodiment, the number of signal wires that supply the selection signals SEL can be reduced to half the number of the signal wires that supply the selection signals SEL in Embodiment 1.

Thus, the signal wires that supply the start signal ST1 or the start signal ST2 can be made common, and the signal wires that supply the selection signals SEL1 to SEL4 can be made common. Accordingly, in the present embodiment, it is possible to further reduce the number of signal wires that supply signals to the scan line driver 46. In the present embodiment, it is also possible to reduce the number of signal wires of the display device 10.

Additionally, as in Embodiment 1, it is possible to suppress threshold value voltage shift of the transistor T0 of the unit circuit 120 of the first stage.

### Embodiment 3

In Embodiments 1 and 2, the selection signals SEL are directly input from the timing controller 42 into the unit circuits 120 of the first stage of the shift registers 110. However, a configuration is possible in which the selection signals SEL are input into the unit circuits 120 of the first stage via a switching circuit 200 that is connected to each unit circuit 120 of the first stage of the shift registers 110 and that outputs, by a switching signal SW, the selection signals SEL to the unit circuits 120 of the first stage. Additionally, a configuration is possible in which the plurality of shift registers 110 that forms the one circuit group 100 forms a plurality of shift register groups 111.

As with the display device 10 of Embodiments 1 and 2, the display device 10 of the present embodiment includes a display panel 20, a touch detector 30, a display controller 40, and a controller 50. With the exception of the display portion 22 and the detection region 23 of the display panel 20, and the scan line driver 46 of the display controller 40, the configuration of the display device 10 of the present embodiment is the same as that of the display device 10 of Embodiments 1 and 2. As such, here, the display portion 22 and the detection region 23 of the display panel 20, and the scan line driver 46 are described.

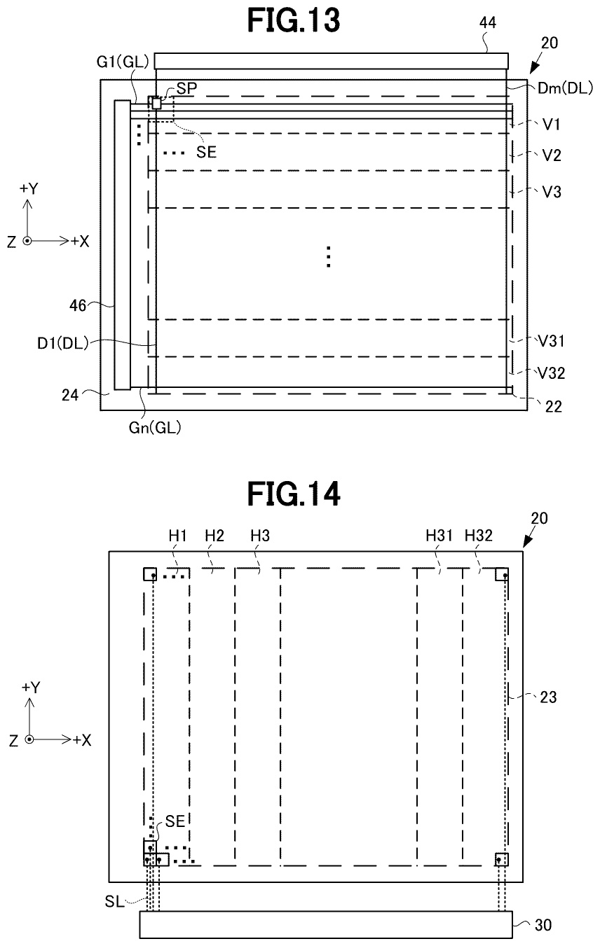

In the present embodiment, as illustrated in FIG. 13, the display portion 22 of the display panel 20 is divided into 32 display regions V1 to V32 that extend in the X direction.

Additionally, as illustrated in FIG. 14, the detection region 23 is divided into 32 detection regions H1 to H32 that extend in the Y direction.

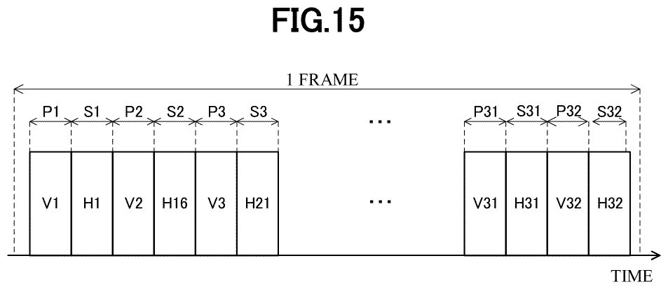

In the present embodiment as well, a display operation for displaying the display element and touch detection are performed in an alternating manner in time divisions within one frame of displaying the display element on the display panel 20. Specifically, as illustrated in FIG. 15, the display operations in the display regions V1 to V32 are sequentially performed in display periods P1 to P32, respectively. The touch detection in one region among the detection regions H1 to H32 is performed in each of detection periods S1 to S32.

The scan line driver 46 of the present embodiment includes 32 shift registers 110V1 to 110V32 that correspond to the display regions V1 to V32 of the display panel 20, respectively. The configuration of the shift registers 110 and the unit circuits 120 of the present embodiment are the same as in Embodiments 1 and 2. Additionally, in the present embodiment as well, each of the shift registers 110V1 to 110V32 subsequently outputs the scan signal from each of the unit circuits 120 as a result of the start signal ST and the selection signals SEL being input into the unit circuits 120 of the first stage of each of the shift registers 110V1 to 110V32.

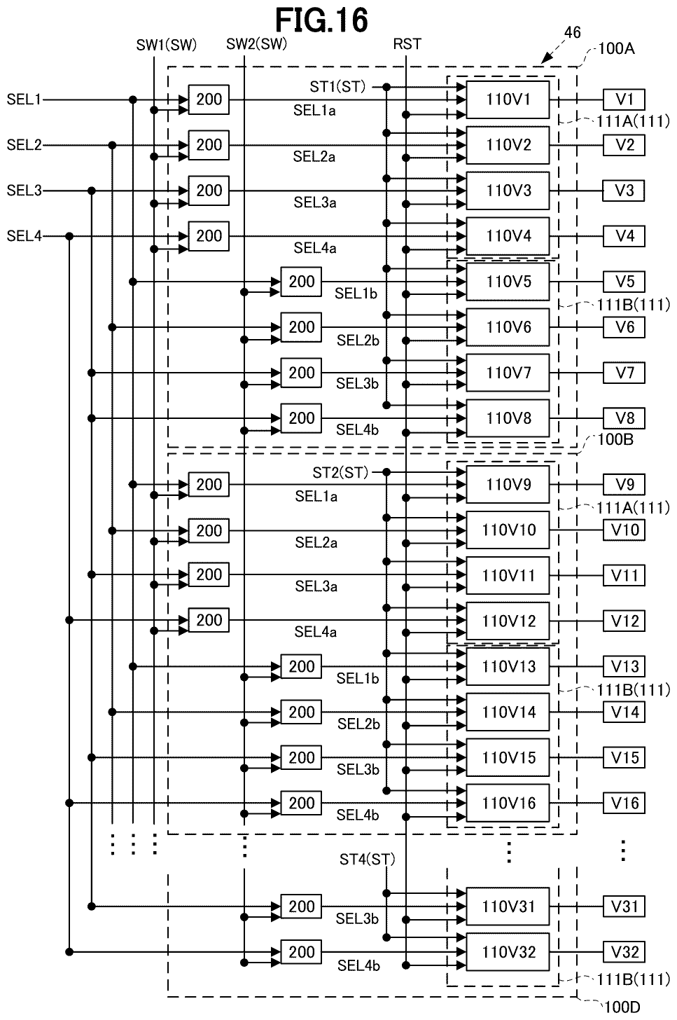

As with the shift registers 110 of Embodiment 2, the shift registers 110 of the present embodiment form a plurality of circuit groups 100. In the present embodiment, the shift registers 110V1 to 110V32 form four circuit groups 100A to 100D. Each of the circuit groups 100A to 100D is formed from eight shift registers 110. For example, a circuit group 100A is formed from the shift registers 110V1 to 110V8, as illustrated in FIG. 16.

As with the circuit group 100A of Embodiment 1, the circuit groups 100A to 100D of the present embodiment each sequentially output the scan signals. Additionally, as with the circuit groups 100A, 100B of Embodiment 2, the circuit groups 100A to 100D of the present embodiment sequentially output the scan signals according to the stopping period S.

Furthermore, in one of the circuit groups 100, the shift registers 110 form a plurality of shift register groups 111. The plurality of shift register groups 111 sequentially output the scan signals.

In the present embodiment, the eight shift registers 110 of one of the circuit groups 100 form two shift register groups 111 that each include four shift registers 110. For example, the shift registers 110V1 to 110V4 of the circuit group 100A form a shift register group 111A of the circuit group 100A, and the shift registers 110V5 to 110V8 of the circuit group 100A form a shift register group 111B of the circuit group 100A.

In the present embodiment, as illustrated in FIG. 16, the circuit group 100 includes a

plurality of switching circuits 200. The switching circuits 200 are connected to each unit circuit 120 of the first stage of the shift registers 110. One of the circuit groups 100 includes eight of the switching circuits 200, and one of the shift register groups 111 includes four of the switching circuits 200.

The selection signals SEL and the switching signal SW supplied from the timing controller 42 are input into the switching circuits 200. The switching circuits 200 output the selection signals SEL to the unit circuits 120 of the first stage on the basis of the switching signal SW. That is, the switching circuits 200 control whether the selection signals SEL are input into the unit circuits 120 of the first stage.

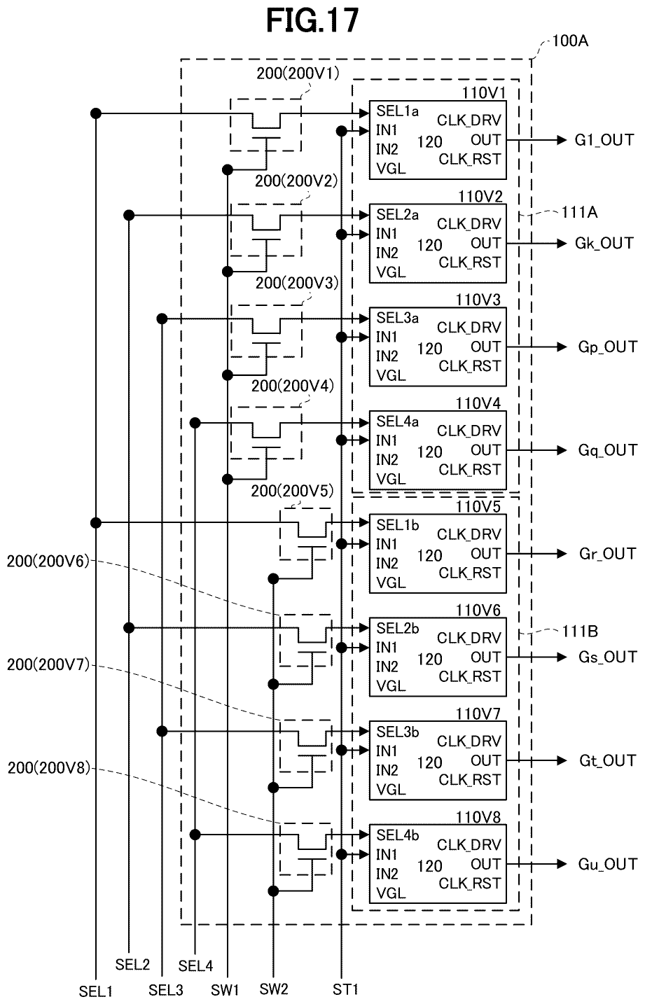

As illustrated in FIG. 17, the switching circuits 200 are switch circuits that are, for example, formed from TFTs. Additionally, the switching signal SW is one of the control signals GSI supplied from the timing controller 42. Note that the clock signal CLK_A, the low-level voltage VGL, and the like are omitted from FIG. 17.

Next, the signals input into the circuit groups 100 of the present embodiment and the output signals are described. The clock signal CLK_A, the low-level voltage VGL, and the like of the present embodiment are the same as in Embodiment 1 and, as such, the start signal ST, the selection signals SEL, and the switching signal SW are described as the signals input into the circuit groups 100.

In the present embodiment, as the start signal ST, start signals ST1 to ST4 are input into the circuit group 100A to the circuit group 100D, respectively. As with the start signal ST1 and the start signal ST2 of Embodiment 2, after the outputting of the scan signal of the previous circuit group 100 (outputting of the unit circuit 120 of the final stage) is ended, an interval equivalent to the stopping period S is provided and, then, each of the start signals ST1 to ST4 is input into the corresponding circuit group 100. As a result, the circuit groups 100A to 100D sequentially output the scan signals. For example, with the configuration illustrated in FIG. 16, after the outputting of the scan signals of the circuit group 100A (the outputting of the unit circuit 120 of the final stage of the shift register 110V8) is ended, an interval equivalent to the stopping period S is provided and, then, the start signal ST2 is started to be input into the circuit group 100B.

As with the start signals ST1 and ST2 of Embodiment 2, each of the start signals ST1 to ST4 is commonly input into each unit circuit 120 of the first stage of the shift registers 110, of the circuit group 100 into which each of the start signals ST1 to ST4 is input. As a result, as in Embodiment 2, the signal wires that supply the start signals ST can be made common and the number of signal wires can be reduced. Except for the start signals ST, the signals input into the circuit group 100A and the signals input into the circuit groups 100B to 100D are the same. As such, in the following, an example is described of the selection signals SEL, the switching signal SW, and the output signals using the circuit group 100A as an example.

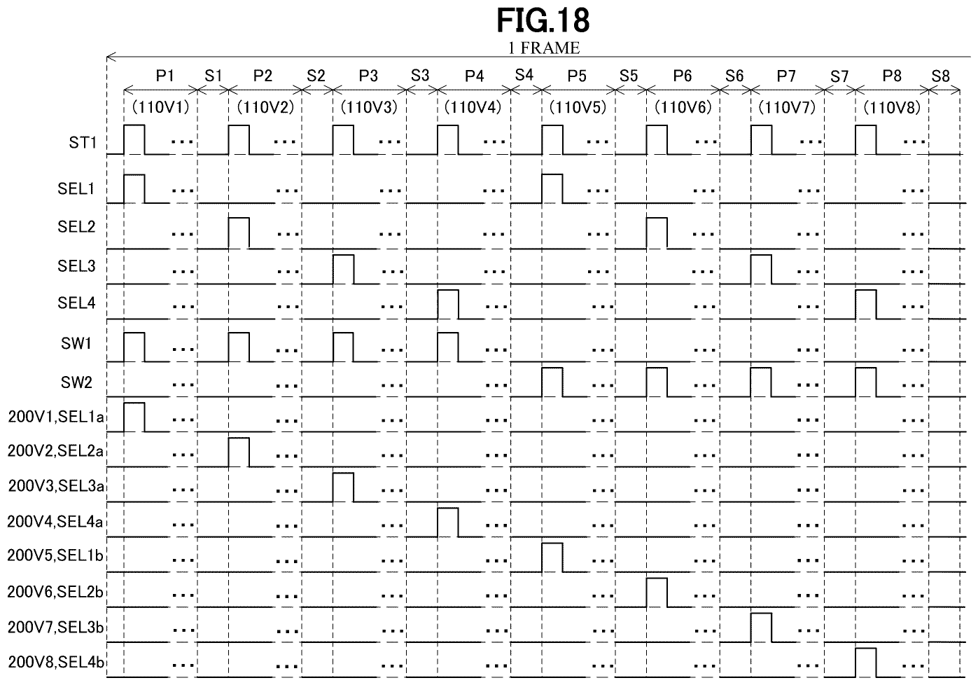

In the present embodiment, each of the selection signals SEL1 to SEL4 are input into each of the switching circuits 200 of one of the shift register groups 111 of the circuit group 100. As illustrated in FIG. 18, the selection signals SEL1 to SEL4 have mutually different phases according to the scan period P and the stopping period S. Additionally, each of the selection signals SEL1 to SEL4 is commonly input into each of the switching circuits 200 of the shift register group 111. As a result, as in Embodiment 2, the signal wires that supply the selection signals SEL1 to SEL4 can be made common and the number of signal wires can be reduced.

For example, each of the selection signals SEL1 to SEL4 is input into each of the switching circuits 200 of the shift register group 111A of the circuit group 100A. Each of the selection signals SEL1 to SEL4 is commonly input into each of the switching circuits 200 of the shift register group 111A of the circuit group 100A, into each of the switching circuits 200 of the other shift register group 111B of the circuit group 100A and, also into each of the switching circuits 200 of the shift register groups 111A, 111B of the circuit groups 100B to 100D.

In the present embodiment, switching signals SW1, SW2 are input into the switching circuits 200 as the switching signal SW. Each of the switching signals SW1, SW2 is input into the switching circuits 200 at a timing that differs for every shift register group 111, with the phase of the switching signal SW1, SW2 matched to the phase of each of the selection signals SEL1 to SEL4. Additionally, the switching signal SW1 is commonly input into each of the switching circuits 200 of the shift register group 111A of the circuit groups 100A to 100D, and the switching signal SW2 is commonly input into each of the switching circuits 200 of the shift register group 111B of the circuit groups 100A to 100D. As a result, the signal wires that supply the switching signals SW1, SW2 can be made common, and the number of signal wires can be reduced.

For example, as illustrated in FIGS. 17 and 18, the switching signal SW1 is input, at the same timing as the selection signal SEL1, into the switching circuit 200 (hereinafter referred to as “switching circuit 200V1”) connected to the unit circuit 120 of the first stage of the shift register 110V1 of the shift register group 111A of the circuit group 100A. The switching circuits 200 output the selection signals SEL to the unit circuits 120 of the first stage on the basis of the switching signal SW. Accordingly, the switching circuit 200V1 outputs, as the selection signal SEL, a selection signal SEL1a to the unit circuit 120 of the first stage of the shift register 110V1. The selection signal SEL1a is input into the unit circuit 120 of the first stage of the shift register 110V1. At the same timing as the inputting of the selection signal SEL1a, the start signal ST1 is input into the unit circuit 120 of the first stage of the shift register 110V1 and, as a result, the shift register 110V1 sequentially outputs the output signals from the unit circuit 120 (display period P1).

Next, at the same timing as the selection signal SEL2, the switching signal SW1 is input into the switching circuit 200 (hereinafter referred to as “switching circuit 200V2”) connected to the unit circuit 120 of the first stage of the shift register 110V2 of the shift register group 111A of the circuit group 100A. In this case, as with the switching circuit 200V1, the switching circuit 200V2 outputs, as the selection signal SEL, a selection signal SEL2a to the unit circuit 120 of the first stage of the shift register 110V2. Then, the selection signal SEL2a and the start signal ST1 are input into the unit circuit 120 of the first stage of the shift register 110V2 and, as a result, the shift register 110V2 sequentially outputs the output signals from the unit circuit 120 (display period P2).

For the shift registers 110V3, V4 of the shift register group 111A of the circuit group 100A as well, the output signals are sequentially output from the unit circuits 120 (display periods P3, P4) in accordance with selection signals SEL3a, SEL4a that are input from the switching circuits 200 (switching circuits 200V3, 200V4) connected to the unit circuits 120 of the first stage and the start signal ST1.

The switching signal SW2 is input, at a timing different from the switching signal SW1, into the switching circuits 200 of the shift register group 111B of the circuit group 100A. Specifically, the switching signal SW2 is input into the switching circuits 200 of the shift register group 111B after the inputting of the switching signal SW1 into the switching circuits 200 (switching circuits 200V1 to 200V4) of the shift register group 111A is ended.

Firstly, the switching signal SW2 is input, at the same timing as the selection signal SEL1, into the switching circuit 200 (hereinafter referred to as “switching circuit 200V5”) connected to the unit circuit 120 of the first stage of the shift register 110V5 of the shift register group 111B of the circuit group 100A. In this case, as with the switching circuits 200V1 to 200V4, the switching circuit 200V5 outputs, as the selection signal SEL, a selection signal SEL1b to the unit circuit 120 of the first stage of the shift register 110V5. Then, the selection signal SEL1b and the start signal ST1 are input into the unit circuit 120 of the first stage of the shift register 110V5 and, as a result, the shift register 110V5 sequentially outputs the output signals from the unit circuit 120 (display period P5).

For the shift registers 110V6 to 110V8 of the shift register group 111B of the circuit group 100A as well, the output signals are sequentially output from the unit circuits 120 (display periods P6 to P8) in accordance with selection signals SEL2b to SEL4b that are input from the switching circuits 200 (switching circuits 200V6 to 200V8) connected to the unit circuits 120 of the first stage and the start signal ST1.

In the circuit groups 100B to 100D as well, as with the circuit group 100A, the start signals ST, the selection signals SEL, the switching signals SW, and the like are input, and the output signals are sequentially output.

In the present embodiment, four selection signals SEL are input into the circuit group 100 formed from eight shift registers 110. The inputting of the four selection signals SEL (SEL1 to SEL4) into the shift registers 110 is controlled by the switching circuits 200, and the four selection signals SEL (SEL1 to SEL4) are respectively input into the eight shifts registers 110 as eight selection signals SEL (SEL1a to SEL4a, and SEL1b to SEL4b). Accordingly, even when signal wires that supply the switching signals SW to the switching circuits 200 are provided, the scan line driver 46 of the present embodiment can reduce the number of signal wires that supply signals compared to the scan line driver 46 that is not provided with the switching circuits 200.

For example, when, as in Embodiment 2, the display portion 22 is divided into 32 display regions V1 to V32, the detection region 23 is divided into 32 detection regions H1 to H32, and four circuit groups 100 are formed from 32 shift registers 110, 16 signals (the start signals ST1 to ST4, the selection signals SEL1 to SEL8, the reset signal RST, the clock signals CLK_A and CLK_B, and the frame reset signal FRM) are required. Meanwhile, in the present embodiment, the number of required signals is merely 14 (the start signals ST1 to ST4, the selection signals SEL1 to SEL4, the switching signals SW1, SW2, the reset signal RST, the clock signals CLK_A and CLK_B, and the frame reset signal FRM).

Thus, in the present embodiment as well, the signal wires that supply the start signals ST can be made common, and the signal wires that supply the selection signals SEL can be made common. Furthermore, the switching circuits 200 control the inputting of the selection signals SEL into the shift registers 110 and, as such, the number of signal wires that supply the selection signals SEL can be reduced, and the signal wires that supply the switching signals SW to the switching circuits 200 can be made common. As a result, it is possible to further reduce the number of signal wires that supply signals to the scan line driver 46.

### Modified Examples

Embodiments have been described, but various modifications can be made to the present disclosure without departing from the spirit and scope of the present disclosure.

In the embodiments, an in-cell type color liquid crystal display panel is used as the display panel 20, but a configuration is possible in which the display panel 20 is implemented as a different display panel. For example, a configuration is possible in which the display panel 20 is implemented as an organic light emitting diode (OLED) display panel.

For example, in the embodiments, the display portion 22 of the display panel 20 is divided into eight display regions V1 to V8. However, the display portion 22 may be divided into a desired number of regions.

The detection region 23 may be divided into a desired number of regions. Additionally, the detection regions H1 to H8 may extend in the X direction.

In the embodiments, the common electrode of the display panel 20 is divided and the divided common electrodes constitute the sensor electrodes SE. However, a configuration is possible in which the sensor electrodes SE are provided on the display panel 20 separate from the common electrode.

A configuration is possible in which the touch detector 30 is implemented as a touch control IC.

A configuration is possible in which the unit circuits 120 and the shift registers 110 are formed from TFTs on a substrate that constitutes the display panel 20. When the unit circuits 120 and the shift registers 110 are formed from TFTs, the semiconductor portion of each TFT is formed from amorphous silicon, low-temperature polysilicon, an oxide semiconductor, or the like.

In the embodiments, the transistors T0 to T8 of the unit circuits 120 are n-type, but a configuration is possible in which the transistors T0 to T8 are p-type.

In Embodiment 2, the scan line driver 46 includes two circuit groups 100A, 100B. However, a configuration is possible in which the scan line driver 46 includes three or more circuit groups. Additionally, the number of shift registers 110 that form one circuit group may be set as desired. It is sufficient that the total number of shift registers 110 of the scan line driver 46 corresponds to the number of regions into which the display portion 22 is divided.

In the embodiments, the scan line driver 46 is implemented as a circuit that is formed in the frame portion 24. However, a configuration is possible in which the scan line driver 46 is provided in the frame portion 24 as a scan line driver IC. Additionally, a configuration is possible in which the scan line driver 46 is built into a TDDI.

In Embodiment 3, the shift registers 110 form a plurality of circuit groups 100. However, a configuration is possible in which the switching circuits 200 are applied to a scan line driver 46 in which the shift registers 110 form one circuit group 100, as in Embodiment 1.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A display device, comprising:
a display panel that includes a plurality of scan lines, and a display portion that is divided into a plurality of display regions;
a scan line driver that sequentially outputs a scan signal to each of the scan lines; and
a touch detector that detects a touch on the display panel, wherein
the scan line driver includes at least one circuit group,
the circuit group includes a plurality of shift registers that include a plurality of unit circuits that are multi-stage connected, and that output the scan signal to each of the scan lines, and the plurality of shift registers sequentially output the scan signal to each of the scan lines within each of the display regions,
the touch detector detects the touch on the display panel in a stopping period in which the at least one circuit group stops outputting of the scan signal, and
in the one circuit group
each of the shift registers sequentially outputs the scan signal as a result of a selection signal, for selecting the shift register to output the scan signal, and a start signal, for starting the outputting of the scan signal, being input into the unit circuit of each first stage,
each of the selection signal input into each of the unit circuits of the first stage has a phase that mutually differs according to a scan period in which the circuit group outputs the scan signal and the stopping period, and
the start signal is commonly input into each of the unit circuits of the first stage.

2. The display device according to claim 1, wherein
the scan line driver includes a plurality of the circuit group,
the plurality of circuit groups sequentially outputs the scan signal, and
each of the selection signal input into each of the unit circuits of the first stage is commonly input into each of the unit circuits of the first stage of the different circuit groups.

3. The display device according to claim 1, wherein a reset signal for resetting the unit circuit of a final stage is commonly input into each of the unit circuits of the final stage of each of the plurality of shift registers.

4. The display device according to claim 1, wherein
each of the plurality of unit circuits includes
a first transistor that controls the outputting of the scan signal, and that includes a terminal from which the scan signal is output, and
a second transistor that is connected to a node connected to a gate terminal of the first transistor, and boosts the node, and
in the unit circuit of the first stage
the selection signal is input into a first terminal of the second transistor, and
the start signal is input into a gate terminal of the second transistor.

5. The display device according to claim 4, wherein
in the unit circuit of a second stage and thereafter,
the first terminal and the gate terminal of the second transistor are diode connected, and
the scan signal output from the unit circuit of a previous stage is input into the first terminal of the second transistor.

6. The display device according to claim 1, wherein
the circuit group includes a plurality of switching circuits, each being connected to each of the unit circuits of the first stage, and that, in accordance with a switching signal, outputs the inputted selection signal to the unit circuit of the first stage,
in the one circuit group, the plurality of shift registers forms a plurality of shift register groups,
each of the selection signal input into the switching circuits is commonly input into each of the switching circuits of the different shift register groups,
each of the selection signal input into each of the switching circuits connected to the unit circuit of the first stage of the shift registers forming one of the shift register groups has a phase that mutually differs, and
the switching signal is input into the switching circuits at a timing that mutually differs for each of the shift register groups.

7. The display device according to claim 6, wherein the switching circuits are switch circuits that switch, in accordance with the switching signal, whether to output the selection signal.

8. A driving method for a display device including
a display panel including a plurality of scan lines and a display portion divided into a plurality of display regions, a display operation of displaying a display element and a touch detection being performed in an alternating manner, the driving method comprising:
displaying the display element or a portion of the display element in one of the display regions by sequentially outputting, from one of a plurality of shift registers that include a plurality of unit circuits and that sequentially output a scan signal to each of the scan lines within each of the plurality of display regions, the scan signal to each of the scan lines, the plurality of unit circuits being multi-stage connected and outputting the scan signal to the scan line; and
detecting a touch on the display panel in a stopping period in which the plurality of shift registers stops outputting of the scan signal, wherein
in the displaying of the display element or a portion of the display element,
the scan signal is sequentially output from the one shift register of the plurality of shift registers as a result of a selection signal, for selecting the shift register to output the scan signal, and a start signal, for starting the outputting of the scan signal, being input into the unit circuit of a first stage of each of the shift registers,
each of the selection signal input into each of the unit circuits of the first stage has a phase that mutually differs according to a scan period in which the plurality of the shift registers outputs the scan signal and the stopping period, and
the start signal is commonly input into each of the unit circuits of the first stage.
